(19) United States
(12) Patent Application Publication
(10) Pub. No.: US 2011/0227180 A1
(43) Pub. Date: Sep. 22, 2011

(54) SOLID-STATE IMAGING DEVICE AND METHOD FOR MANUFACTURING SAME

(75) Inventor: Atsushi MURAKOSHI, Oita-ken (JP)

(73) Assignee: KABUSHIKI KAISHA TOSHIBA, Tokyo (JP)

(21) Appl. No.: 12/883,483

(22) Filed: Sep. 16, 2010

(30) Foreign Application Priority Data
Mar. 19, 2010 (JP) 2010-063463

(51) Int. Cl. H01L 31/0232; H01L 31/02; H01L 31/18; H01L 21/66; H01L 21/50

(52) U.S. Cl. 257/432; 257/431; 438/15; 257/E31.127; 257/E31.11; 257/E21.53; 257/E21.499

(57) ABSTRACT

According to one embodiment, a solid-state imaging device includes a multilayer wiring layer, a semiconductor substrate, an impurity diffusion region of a second conductivity type, an anti-reflection film, a color filter, and a metallic layer. The semiconductor substrate is provided on the multilayer wiring layer and includes a first conductivity type layer. The impurity diffusion region of the second conductivity type partitions the first conductivity type layer into a plurality of regions. The anti-reflection film is provided on the semiconductor substrate. The color filter is provided on the anti-reflection film for each of the partitioned regions. The metallic layer is formed in a region of a lower surface of the semiconductor substrate except the partitioned regions. The anti-reflection film is not provided in a region immediately above the metallic layer.

### CROSS-REFERENCE TO RELATED APPLICATIONS

This application is based upon and claims the benefit of priority from the prior Japanese Patent Application No. 2010-63463, filed on Mar. 19, 2010; the entire contents of which are incorporated herein by reference.

### FIELD

Embodiments described herein relate generally to a solid-state imaging device and a method for manufacturing the same.

### BACKGROUND

Conventionally, a front-illuminated solid-state imaging device has been developed. In the front-illuminated solid-state imaging device, a multilayer wiring layer is provided on the surface of a semiconductor substrate. Color filters and microlenses are provided on the multilayer wiring layer. Photodiodes are formed in a superficial portion of the semiconductor substrate. Transfer gates are formed in the multilayer wiring layer. The photodiode is formed from, for example, an n-type diffusion region and partitioned for each pixel by a p-type barrier layer. Light injected into the semiconductor substrate from above via the microlens, the color filter, and the multilayer wiring layer is photoelectrically converted by the photodiode. The generated electrons are read out via the transfer gate.

In such a front-illuminated solid-state imaging device, light incident from outside is injected into the semiconductor substrate through the interior of the multilayer wiring layer. Hence, the light utilization efficiency is low. Thus, with the reduction of pixel size, the amount of light injected into the photodiode of each pixel decreases, causing a problem of decreased sensitivity. Furthermore, with the reduction of pixel size, the distance between the pixels is also shortened. Hence, light injected into one pixel may be diffused by the metal wiring in the multilayer wiring layer and injected into another pixel, causing another problem of color mixing. Color mixing results in decreasing the color resolution, and it is impossible to distinguish subtle differences in color.

To solve these problems, a back-illuminated solid-state imaging device is proposed (see, e.g., JP-A 2003-031785 (Kokai)). In the back-illuminated solid-state imaging device, light is injected from the back side of the semiconductor substrate, i.e., from the side not provided with the multilayer wiring layer. The back-illuminated solid-state imaging device has high light utilization efficiency and high sensitivity because light incident from outside is injected into the semiconductor substrate without the intermediary of the multilayer wiring layer.

In the back-illuminated solid-state imaging device, the problem is how to extract a wiring from the multilayer wiring layer. In view of how the solid-state imaging device is mounted, it is desirable that the wiring be extracted upward, i.e., to the light incident side. Thus, the following configuration can be contemplated. A large hole is formed in the semiconductor substrate. The wiring in the multilayer wiring layer is exposed to the bottom of this hole. Wire bonding is directly performed on this exposed wiring through the hole.

However, in this case, when color filters are formed on the semiconductor substrate, the wire bonding portion cannot be used as a marker for alignment. Thus, when color filters are formed, irradiation with infrared radiation is performed from the support substrate side. The infrared radiation transmitted through the support substrate, the multilayer wiring layer, and the semiconductor substrate is used to identify the shadow of the uppermost wiring, which is used as a marker.

However, in such a solid-state imaging device, the uppermost wiring in the multilayer wiring layer is positioned with reference to a wiring therebelow. The lowermost wiring in the multilayer wiring layer is positioned with reference to the contact. The contact is positioned with reference to the gate electrode. The gate electrode is positioned with reference to the STI (shallow trench isolation) formed in the lower surface of the semiconductor substrate. Accordingly, the color filter is indirectly positioned using the STI as a first reference, in the order of STI, gate electrode, contact, lowermost wiring, one or more intermediate wirings, uppermost wiring, and color filter. On the other hand, the barrier layer partitioning the pixel is also positioned with reference to the STI.

Thus, the relative positional relationship between the color filter and the barrier layer is indirectly determined with a number of components intervening therebetween, and hence widely varied. As a result, with the miniaturization of pixels, it is difficult to position the boundary of the color filter in a region immediately above the barrier layer. Accordingly, high integration of pixels is difficult.

### BRIEF DESCRIPTION OF THE DRAWINGS

FIG. 1 is a plan view illustrating a solid-state imaging device according to an embodiment;

FIG. 2 is a cross-sectional view illustrating the solid-state imaging device according to the embodiment;

FIG. 3 is a partially enlarged cross-sectional view illustrating the solid-state imaging device according to the embodiment;

FIG. 4 is a plan view illustrating an electrode pad region of the solid-state imaging device according to the embodiment;

FIG. 5 is a cross-sectional view taken along line A-A′ shown in FIG. 4;

FIG. 6 is a process cross-sectional view illustrating a method for manufacturing the solid-state imaging device according to the embodiment;

FIG. 7 is a process cross-sectional view illustrating the method for manufacturing the solid-state imaging device according to the embodiment;

FIG. 8 is a process cross-sectional view illustrating the method for manufacturing the solid-state imaging device according to the embodiment;

FIG. 9 is a process cross-sectional view illustrating the method for manufacturing the solid-state imaging device according to the embodiment;

FIG. 10 is a process cross-sectional view illustrating the method for manufacturing the solid-state imaging device according to the embodiment;

FIG. 11 is a process cross-sectional view illustrating the method for manufacturing the solid-state imaging device according to the embodiment;

FIG. 12 is a process cross-sectional view illustrating the method for manufacturing the solid-state imaging device according to the embodiment;

FIG. 13 is a process cross-sectional view illustrating the method for manufacturing the solid-state imaging device according to the embodiment;

FIG. 14 is a process cross-sectional view illustrating the method for manufacturing the solid-state imaging device according to the embodiment;

FIG. 15 is a process cross-sectional view illustrating the method for manufacturing the solid-state imaging device according to the embodiment;

FIG. 16 is a process cross-sectional view illustrating the method for manufacturing the solid-state imaging device according to the embodiment;

FIG. 17 is a process cross-sectional view illustrating the method for manufacturing the solid-state imaging device according to the embodiment;

FIG. 18 is a process cross-sectional view illustrating the method for manufacturing the solid-state imaging device according to the embodiment;

FIG. 19 is a process cross-sectional view illustrating the method for manufacturing the solid-state imaging device according to the embodiment;

FIG. 20 is a process cross-sectional view illustrating the method for manufacturing the solid-state imaging device according to the embodiment;

FIG. 21 is a process cross-sectional view illustrating the method for manufacturing the solid-state imaging device according to the embodiment;

FIG. 22 is a process cross-sectional view illustrating the method for manufacturing the solid-state imaging device according to the embodiment;

FIG. 23 is a process cross-sectional view illustrating the method for manufacturing the solid-state imaging device according to the embodiment;

FIG. 24 is a process cross-sectional view illustrating the method for manufacturing the solid-state imaging device according to the embodiment;

FIG. 25 is a process cross-sectional view illustrating the method for manufacturing the solid-state imaging device according to the embodiment;

FIG. 26 is a process cross-sectional view illustrating the method for manufacturing the solid-state imaging device according to the embodiment;

FIG. 27 is a graph illustrating a boron concentration profile, where the horizontal axis represents a position in a vertical direction, and the vertical axis represents boron concentration; and

FIG. 28 is a graph illustrating the attenuation behavior of light in silicon, where the horizontal axis represents the thickness of a silicon substrate reducing the intensity of incident light by half, and the vertical axis represents the wavelength of incident light.

### DETAILED DESCRIPTION

In general, according to one embodiment, a solid-state imaging device includes a multilayer wiring layer, a semiconductor substrate, an impurity diffusion region of a second conductivity type, an anti-reflection film, a color filter, and a metallic layer. The semiconductor substrate is provided on the multilayer wiring layer and includes a first conductivity type layer. The impurity diffusion region of the second conductivity type partitions the first conductivity type layer into a plurality of regions. The anti-reflection film is provided on the semiconductor substrate. The color filter is provided on the anti-reflection film for each of the partitioned regions. The metallic layer is formed in a region of a lower surface of the semiconductor substrate except the partitioned regions. The anti-reflection film is not provided a region immediately above the metallic layer.

According to another embodiment, a method is disclosed for manufacturing a solid-state imaging device. The method can form an impurity diffusion region of a second conductivity type in a substrate to partition a first conductivity type layer into a plurality of regions. At least a lower portion of the substrate is made of a semiconductor material. The first conductivity type layer is provided in the lower portion. In addition, the method can form a metallic layer in a region of a lower surface of the substrate except the partitioned regions, form a multilayer wiring layer below the substrate, remove an upper portion of the substrate to make the lower portion of the substrate as a semiconductor substrate, form an anti-reflection film on at least a part of a region of an upper surface of the semiconductor substrate except a region immediately above the metallic layer, and form a color filter on an upper surface of the anti-reflection film for each of the partitioned regions using the metallic layer as an alignment mark.

An Embodiment of the invention will now be described.

First, the embodiment is schematically described.

The features of a solid-state imaging device according to this embodiment are as follows. A silicon substrate is provided on a multilayer wiring layer; a photodiode is formed as a light receiving element in the silicon substrate; a color filter and the like are provided on the silicon substrate; and a silicide layer is formed on the device formation surface of the silicon substrate in a back-illuminated solid-state imaging device to be illuminated with light from above. In the back-illuminated solid-state imaging device, the silicon substrate is thin enough to partially transmit light, and silicide has higher light reflectance than silicon oxide and silicon. Hence, the silicide layer can be optically detected via the silicon substrate. Thereby, this silicide layer can be used as an alignment mark during manufacturing. Furthermore, a through hole is formed in the silicon substrate, and an electrode film is formed on the inner surface of the through hole. This electrode film is connected to the metal wiring of the multilayer wiring layer at the bottom of the through hole and extracted to above the upper surface of the silicon substrate. This extracted portion constitutes an electrode pad to which an external wiring is to be bonded.

Next, the configuration of the solid-state imaging device according to this embodiment will now be described in detail with reference to the drawings.

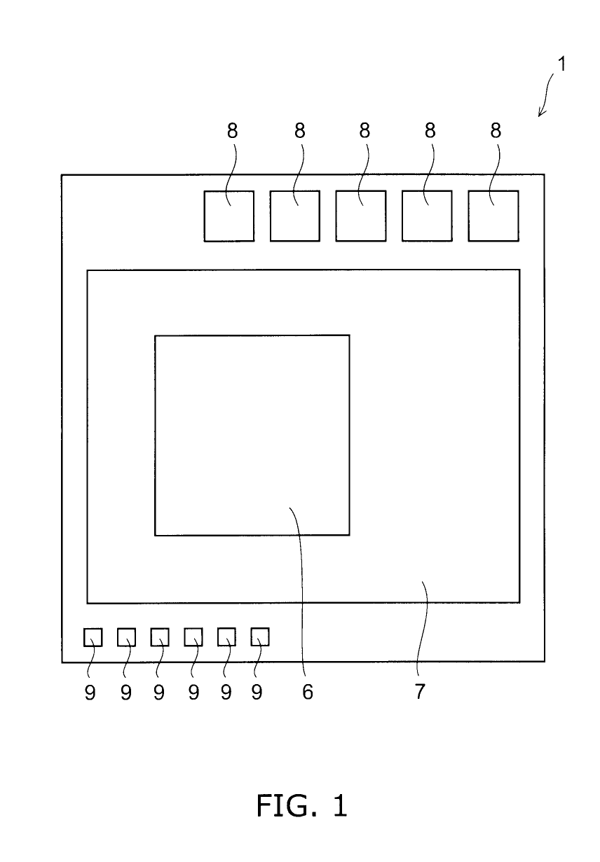

FIG. 1 is a plan view illustrating the solid-state imaging device according to this embodiment.

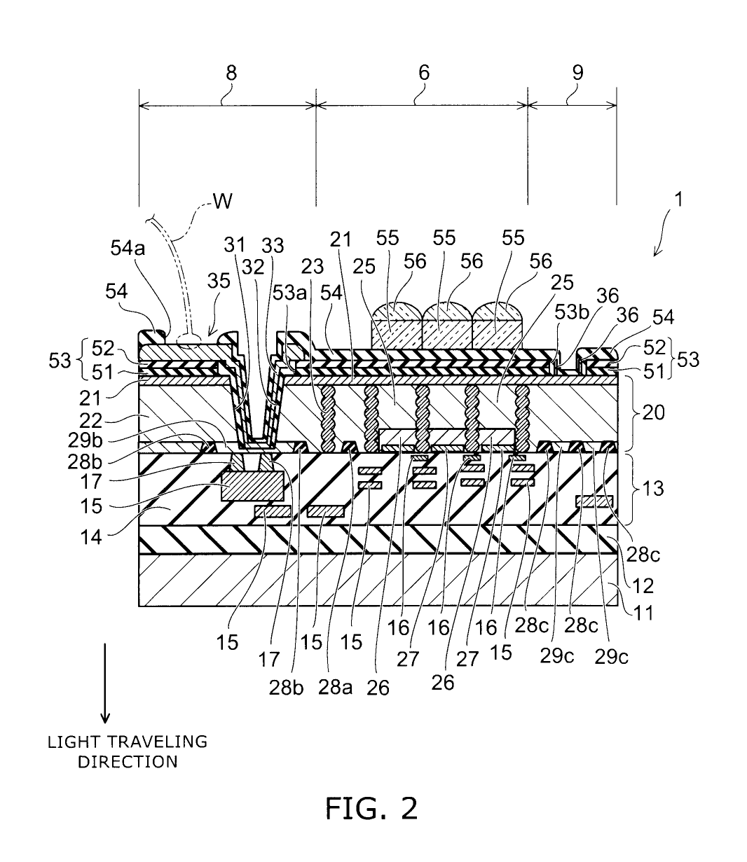

FIG. 2 is a cross-sectional view illustrating the solid-state imaging device according to this embodiment.

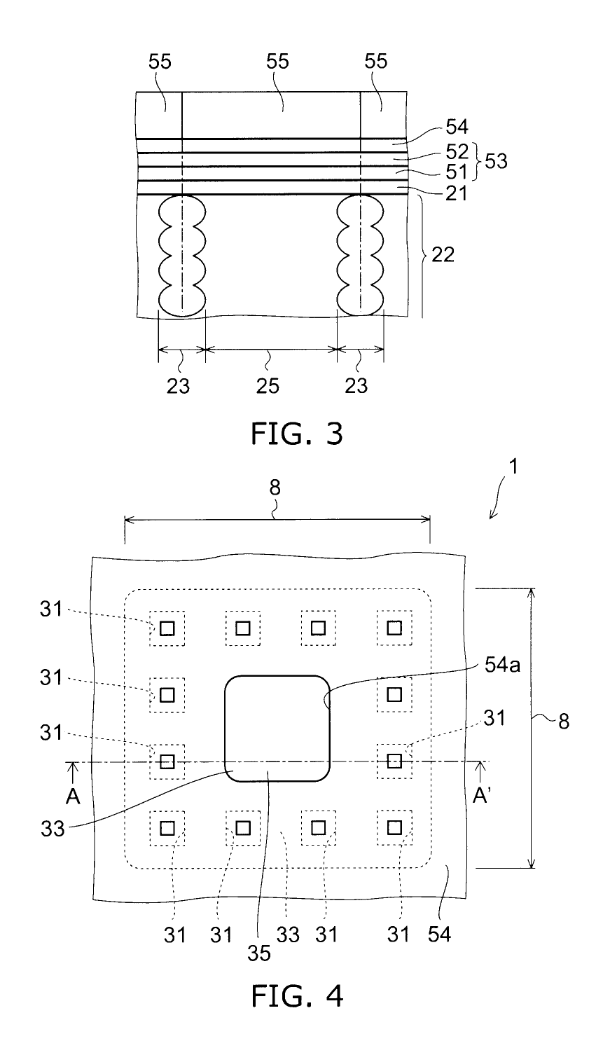

FIG. 3 is a partially enlarged cross-sectional view illustrating the solid-state imaging device according to this embodiment.

FIG. 4 is a plan view illustrating an electrode pad region of the solid-state imaging device according to this embodiment.

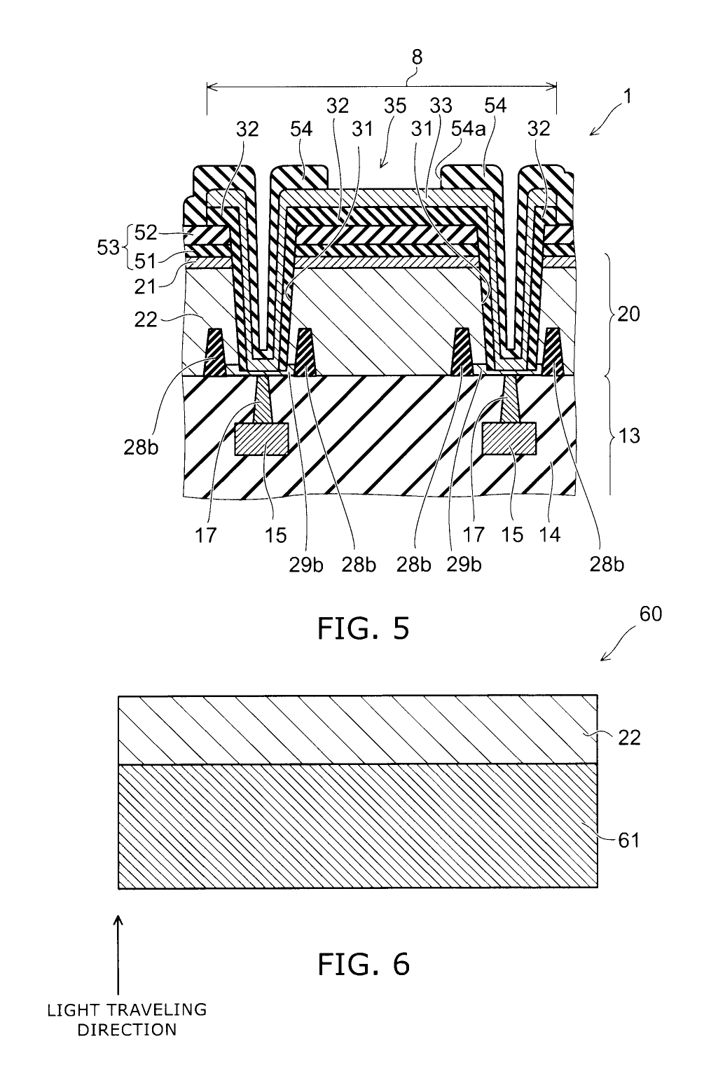

FIG. 5 is a cross-sectional view taken along line A-A′ shown in FIG. 4.

In FIG. 2, for clarity of illustration, only the characteristic portions are shown in a simplified manner. Thus, FIG. 2 is not in exact agreement with FIG. 1, FIG. 4, and FIG. 5.

In the following, in the description of the configuration of the solid-state imaging device (see FIG. 1 to FIG. 5), the average traveling direction of light (light traveling direction) during imaging by the solid-state imaging device is referred to as “downward” or “below”. The direction opposite thereto is referred to as “upward” or “above”. The direction orthogonal to the upward and downward direction is referred to as “lateral”. On the other hand, in the description of a method for manufacturing the solid-state imaging device (see FIG. 6 to FIG. 26), the fixed surface fixed to a holder and the like is referred to as “lower surface”. The processing surface is referred to as “upper surface”. The notations “downward/below” and “upward/above” are conformed thereto. As described later, in the method for manufacturing a solid-state imaging device according to this embodiment, the processing surface is inverted in midstream. Hence, in the description of the manufacturing method, the notations “downward/below” and “upward/above” are also inverted. This will be mentioned as needed.

As shown in FIG. 1, a solid-state imaging device 1 according to this embodiment includes a light receiving region 6 for receiving light and converting the light to an electrical signal. As viewed from above, the outer edge of the light receiving region 6 has a rectangular shape. The light receiving region 6 includes numerous pixels arranged in a matrix. The light receiving region 6 is surrounded by a peripheral circuit region 7 for driving the light receiving region 6 and processing the electrical signal outputted from the light receiving region 6. The outer edge of the peripheral circuit region 7 also has a rectangular shape. In addition, the solid-state imaging device 1 includes one or more electrode pad regions 8, and one or more mark material regions 9.

As shown in FIG. 2, the solid-state imaging device 1 includes a support substrate 11. The support substrate 11 is responsible for the strength and stiffness of the overall solid-state imaging device 1 and formed from, for example, silicon. A passivation film 12 illustratively made of silicon oxide is provided on the support substrate 11, and a multilayer wiring layer 13 is provided thereon. In other words, the support substrate 11 is attached to the lower surface of the multilayer wiring layer 13 via the passivation film 12. In the multilayer wiring layer 13, a plurality of metal wirings 15 are provided in multiple layers in an interlayer insulating film 14 made of, for example, an insulating material such as silicon oxide. The light receiving region 6 includes a transfer gate 16 in the uppermost portion of the multilayer wiring layer 13.

On the multilayer wiring layer 13, a silicon substrate 20 made of single crystal silicon is provided. The silicon substrate 20 has a thickness of, for example, 3 to 5 μm, more particularly 4.7 μm. In the silicon substrate 20, a p-type layer 21 is formed in the uppermost portion, and a portion except the p-type layer 21 is an n-type layer 22. A silicon oxide film 51 is provided on the upper surface of the silicon substrate 20, and a silicon nitride film 52 is provided thereon. The silicon oxide film 51 and the silicon nitride film 52 constitute an anti-reflection film 53. The anti-reflection film 53 is a film that suppresses reflection of visible light. A cap film 54 illustratively made of silicon oxide is provided on the anti-reflection film 53. The cap film 54 has a refractive index of, for example, 2 or less.

In the following, the configuration of each of the light receiving region 6, the electrode pad region 8, and the mark material region 9 will now be described.

First, the configuration of the light receiving region 6 is described.

In the light receiving region 6, a p-type barrier region 23 is selectively formed in the n-type layer 22. As viewed from above, for example, the p-type barrier region 23 is shaped like a lattice. The n-type layer 22 is partitioned into a plurality of PD (photodiode) regions 25 by the p-type barrier region 23. Each PD region 25 corresponds to each pixel of the solid-state imaging device 1. The PD regions 25 are electrically isolated from each other by the p-type layer 21 and the p-type barrier region 23. As viewed from above, each PD region 25 has, for example, a generally square shape. The plurality of PD regions 25 are arranged in a matrix.

A high concentration region 26 having n⁺-type conductivity is formed in a lower portion of the PD region 25. On the other hand, the n-type layer 22 remains as-is in the upper portion of the PD region 25. In the lowermost portion of the PD region 25, an inversion preventing layer 27 having p-type conductivity is formed. Thus, the PD region 25 is formed of the high concentration region 26 and the n-type layer 22 and surrounded by the p-type layer 21, the p-type barrier region 23, and the inversion preventing layer 27. The p-type layer 21 is an inversion preventing layer on the light receiving surface side. The high concentration region 26 and the n-type layer 22 are doped with donor impurity, such as phosphorus (P). The p-type layer 21, the p-type barrier region 23, and the inversion preventing layer 27 are doped with acceptor impurity, such as boron (B). A device isolation film 28a illustratively made of silicon oxide is formed in the lower surface of the silicon substrate 20 so as to surround the light receiving region 6. On the other hand, in the peripheral circuit region 7, a readout circuit (not shown) and the like are formed in the lower surface of the silicon substrate 20.

As shown in FIG. 2 and FIG. 3, the light receiving region 6 includes a plurality of color filters 55 on the cap film 54. Each color filter 55 is provided for each PD region 25. For example, the color filter 55 is provided in a region immediately above each PD region 25. In this case, as shown in FIG. 3, the boundary between the adjacent color filters 55 is located in the immediately overlying region of the p-type barrier region 23. The color filters 55 are, for example, a red filter that transmits red light and blocks light of the other colors, a green filter that transmits green light and blocks light of the other colors, and a blue filter that transmits blue light and blocks light of the other colors. A planoconvex microlens 56 is provided on each color filter 55. Thus, each pixel of the solid-state imaging device 1 includes, sequentially from above, one microlens 56, one color filter 55, and one PD region 25. The aforementioned transfer gate 16 is also provided for each pixel. In addition, an amplifier/reset transistor (not shown) is also formed in each pixel.

Next, the configuration of the electrode pad region 8 will now be described.

As shown in FIG. 2, FIG. 4, and FIG. 5, as viewed from above, the electrode pad region 8 has, for example, a generally square shape with rounded corners with a length of, for example, 80 μm on a side. Each electrode pad region 8 includes a plurality of through holes 31. As viewed from above, the through hole 31 has, for example, a square shape with a length of 10 μm on a side. Each through hole 31 extends downward from the upper surface of the anti-reflection film 53 and pierces the anti-reflection film 53, the p-type layer 21, and the n-type layer 22. A portion of the through hole 31 piercing the anti-reflection film 53 constitutes an opening 53a of the anti-reflection film 53. This plurality of through holes 31 are arranged, for example, along the outer edge of the electrode pad region 8.

A silicide layer 29b is formed in a region of the lower surface of the silicon substrate 20, the region including the immediately underlying region of the through hole 31. Furthermore, a frame-shaped device isolation film 28b is formed so as to surround the silicide layer 29b. In other words, the silicide layer 29b is located in a region partitioned by the device isolation film 28b. The device isolation film 28b is formed from, for example, silicon oxide.

A side surface protective film 32 illustratively made of silicon oxide is provided on the side surface of the through hole 31. The side surface protective film 32 is continuously provided throughout the electrode pad region 8 except on the bottom surface of the through hole 31. Furthermore, an electrode film 33 made of a conductive material such as aluminum is provided on the side surface protective film 32 in the electrode pad region 8. The electrode film 33 is continuously provided throughout the electrode pad region 8, including on the bottom surface and side surface of the through hole 31 and on the upper surface of the silicon substrate 20. Accordingly, the electrode film 33 is in contact with the upper surface of the silicide layer 29b at the bottom surface of the through hole 31. A contact 17 is provided in the uppermost portion of the multilayer wiring layer 13, which is a region immediately below the silicide layer 29b. The upper end of the contact 17 is in contact with the lower surface of the silicide layer 29b. The lower end of the contact 17 is connected to the metal wiring 15. Thereby, the electrode film 33 is connected to the contact 17 via the silicide layer 29b.

In the central part of the electrode pad region 8, an opening 54a is formed in the cap film 54. As viewed from above, the opening 54a has, for example, a square shape with rounded corners with a length of, for example, 50 μm on a side. The through hole 31 is not formed in the immediately underlying region of the opening 54a, but the silicon substrate 20 is provided throughout the immediately underlying region. In other words, the cap film 54 covers the peripheral part of a portion of the electrode film 33 located on the upper surface of the silicon substrate 20 and a portion of the electrode film 33 located on the inner surface of the through hole 31, but does not cover the central part of the portion of the electrode film 33 located on the upper surface of the silicon substrate 20. This central part, i.e., a portion of the electrode film 33 exposed in the opening 54a, constitutes an electrode pad 35 to which an external wiring W is to be bonded. In other words, one electrode pad 35 is provided in the central part of the electrode pad region 8, and a plurality of through holes 31 are located therearound. The electrode film 33 is continuously formed from the portion constituting the electrode pad 35 to the portion connected to the silicide layer 29b at the bottom surface of the through hole 31. Thereby, when an external wiring W is bonded to the electrode pad 35, the external wiring W is connected to the metal wiring 15 via the electrode film 33, the silicide layer 29b, and the contact 17.

Next, the configuration of the mark material region 9 will now be described.

In the mark material region 9, a device isolation film 28c is selectively formed in the lower surface of the silicon substrate 20. A silicide layer 29c is formed in the region of the lower surface of the silicon substrate 20 partitioned by the device isolation film 28c. On the silicon substrate 20, an opening 53b is formed in the anti-reflection film 53. In addition, in the opening 53b, a fence 36 is provided along the inner edge of the opening 53b. The fence 36 is formed from the same material as the electrode film 33. For example, the fence 36 is formed from aluminum. On the other hand, the cap film 54 is provided also in the opening 53b, and the fence 36 is buried in the cap film 54. Inside the fence 36 as viewed from above, a portion vertically extending from the cap film 54 to the silicide layer 29c includes no material having low light transmittance such as metal.

Thereby, when the mark material region 9 is irradiated with infrared radiation from above, this infrared radiation is transmitted through the cap film 54 and the silicon substrate 20 to the silicide layer 29c, reflected by the silicide layer 29c, transmitted again through the silicon substrate 20 and the cap film 54, and emitted upward. By receiving this emitted light, the silicide layer 29c can be optically detected. Thus, in each process of the manufacturing processes of the solid-state imaging device 1, the silicide layer 29c can be used as an alignment mark. The number of mark material regions 9 provided in the solid-state imaging device 1 is, for example, equal to the number of processes requiring the alignment mark. In the plurality of mark material regions 9, the shapes of the silicide layers 29c may be different from each other. For example, each of the silicide layers 29c may be shaped like a character or sign. Thereby, the mark material regions 9 can be easily identified. Here, the silicide layers 29b and 29c are formed in the same process. For example, the silicide layers 29b and 29c are salicide layers formed in a self-aligned manner. Furthermore, the silicide layers 29b and 29c are, for example, compounds of silicon with a transition metal such as titanium (Ti), tungsten (W), tantalum (Ta), cobalt (Co), or nickel (Ni).

In contrast, if light transmitted through the silicon substrate 20 is used to detect an alignment mark made of the device isolation film 28c without forming the silicide layers 29b and 29c, sufficient contrast cannot be obtained because of low light reflection intensity at the device isolation film 28c. Thus, the alignment mark cannot be accurately detected. In this case, it is contemplated to increase the intensity of incident light in order to increase the intensity of reflected light. However, this makes the light reflected from the upper surface stronger than the light reflected from the lower surface of the silicon substrate 20. Thus, contrarily, detection of the alignment mark is made difficult.

Next, a method for manufacturing a solid-state imaging device according to this embodiment will now be described.

FIG. 6 to FIG. 26 are process cross-sectional views illustrating the method for manufacturing a solid-state imaging device according to this embodiment.

Here, FIG. 6 to FIG. 26 show the same cross section as FIG. 2, and only the characteristic portions are shown enlarged as in FIG. 2. FIG. 6 to FIG. 8 are vertically inverted with respect to FIG. 2.

First, as shown in FIG. 6, a substrate 60 is prepared. The substrate 60 includes an n-type layer 22 on a p⁺-type base material 61. The p⁺-type base material 61 is made of single crystal silicon doped with acceptor impurity, such as boron, and has a thickness of, for example, 750 μm. On the other hand, the n-type layer 22 is a silicon layer epitaxially grown on the p⁺-type base material 61. The n-type layer 22 is doped with donor impurity, such as phosphorus, and has a thickness of, for example, 3 to 5 μm, more particularly 4.7 μm.

In the following, in the processes shown in FIG. 6 to FIG. 8, the surface of the substrate 60 on the p⁺-type base material 61 side serves as a fixed surface, and the surface on the n-type layer 22 serves as a processing surface. Hence, in the following description, the p⁺-type base material 61 side is referred to as “downward” or “below”, and the n-type layer 22 side is referred to as “upward” or “above”. Although imaging light is not incident during the manufacturing of the solid-state imaging device 1, the same arrow indicating the “light traveling direction” as in FIG. 2 is shown also in FIG. 6 to FIG. 26 for convenience. The “light traveling direction” is fixed with respect to the solid-state imaging device 1 and its intermediate products.

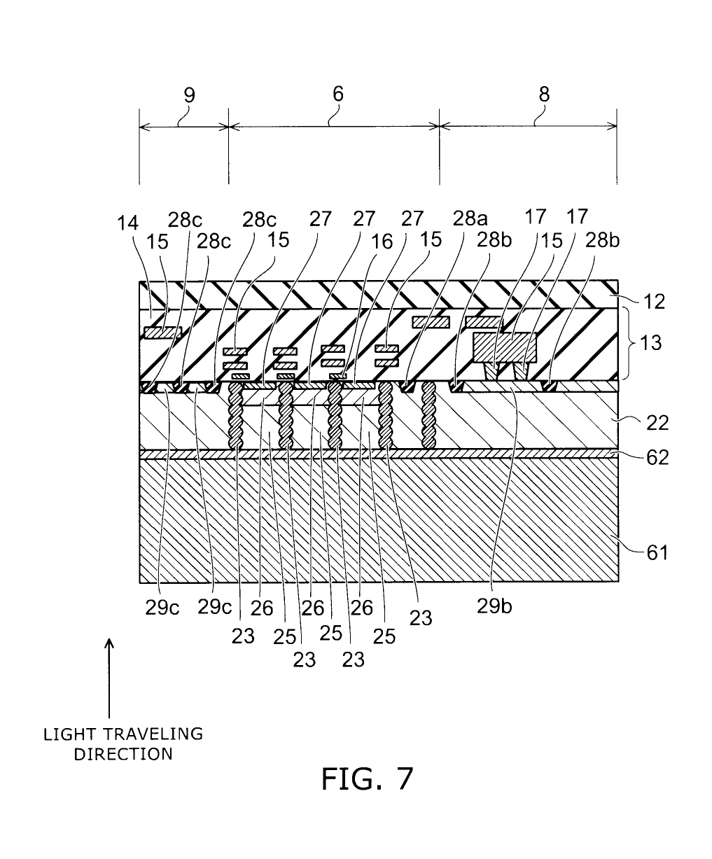

Next, as shown in FIG. 7, device isolation films 28a to 28c are formed in the upper surface of the n-type layer 22. Specifically, trenches are formed in the upper surface of the n-type layer 22, and silicon oxide is deposited therein. Thus, a frame-shaped device isolation film 28a is formed in the light receiving region 6, a frame-shaped device isolation film 28b is formed in the electrode pad region 8, and a device isolation film 28c having an arbitrary shape is formed in the mark material region 9. Next, the device isolation film 28a is used as an alignment mark to ion-implant boron into the n-type layer 22 multiple times. Thus, a lattice-shaped p-type barrier region 23 is formed in the light receiving region 6. At this time, the p-type barrier region 23 is formed so as to partition the n-type layer 22 into a plurality of portions.

Next, donor impurity is ion-implanted into an upper portion of the n-type layer 22 in the light receiving region 6 to form a high concentration region 26. At this time, in each portion partitioned by the p-type barrier region 23, a portion below the high concentration region 26 remains unchanged as the n-type layer 22. Next, acceptor impurity is implanted into an uppermost portion of the n-type layer 22 in the light receiving region 6 to form an inversion preventing layer 27. Thereby, each portion partitioned by the p-type barrier region 23 constitutes a photodiode (PD) region 25.

Next, a silicide block layer (not shown) illustratively made of silicon oxide is formed entirely on the n-type layer 22. Then, the silicide block layer is selectively removed to expose a region intended to form a silicide layer in the upper surface of the n-type layer 22. Specifically, a region surrounded by the device isolation film 28b and a region surrounded by the device isolation film 28c are exposed. At this time, part of the device isolation films 28b and 28c may also be exposed. Next, a metal layer is deposited entirely on the n-type layer 22 so as to cover the silicide block layer. This metal layer is formed from a transition metal such as titanium (Ti), tungsten (W), tantalum (Ta), cobalt (Co), or nickel (Ni). At this time, a region of the upper surface of the n-type layer 22 not covered with the silicide block layer is in contact with this metal layer.

Next, heating treatment is performed at a temperature of, for example, 500° C. Thereby, in the region where the n-type layer 22 is in contact with the metal layer, silicon in the n-type layer 22 reacts with the metal in the metal layer to form a silicide layer. Subsequently, the silicide block layer is removed by, for example, sulfuric acid hydrolysis. At this time, the unreacted metal layer is also removed. Thus, a silicide layer (salicide layer) as a metallic layer is formed in a self-aligned manner with respect to the device isolation film. More specifically, in the upper surface of the n-type layer 22, a silicide layer 29b is formed in the region surrounded by the device isolation film 28b, and a silicide layer 29c is formed in the region surrounded by the device isolation film 28c. The silicide layer 29c is formed in a region of the upper surface of the substrate 60 immediately above a region intended to form a through hole 31 (see FIG. 2)

Next, in the light receiving region 6, the device isolation film 28a is used as an alignment mark to form a transfer gate 16 for each PD region 25. Next, an interlayer insulating film 14 is deposited so as to bury the transfer gate 16. Furthermore, a contact 17 and a plurality of metal wirings 15 are formed in multiple layers in the interlayer insulating film 14. Thus, a multilayer wiring layer 13 is formed. At this time, the lower end of the contact 17 is brought into contact with the silicide layer 29b, and the upper end is connected to the metal wiring 15. The metal wiring 15 may be formed using a metal wiring 15 therebelow or the transfer gate 16 as an alignment mark, or may be formed using the silicide layer 29c of the mark material region 9 as an alignment mark.

On the other hand, in the processes of forming various diffusion layers in the aforementioned n-type layer 22 and forming the multilayer wiring layer 13, amplifier transistors, reset transistors and the like (not shown) are formed in the light receiving region 6. Furthermore, a readout circuit (not shown) and the like are formed in the peripheral circuit region 7. Next, silicon oxide is deposited on the multilayer wiring layer 13 to form a passivation film 12, and the upper surface is planarized by CMP. In the processes up to this, boron contained in the p⁺-type base material 61 diffuses into the n-type layer 22 so that a p-type diffusion layer 62 containing both boron and phosphorus is formed between the p⁺-type base material 61 and the n-type layer 22. The p-type diffusion layer 62 is in contact with the p-type barrier region 23.

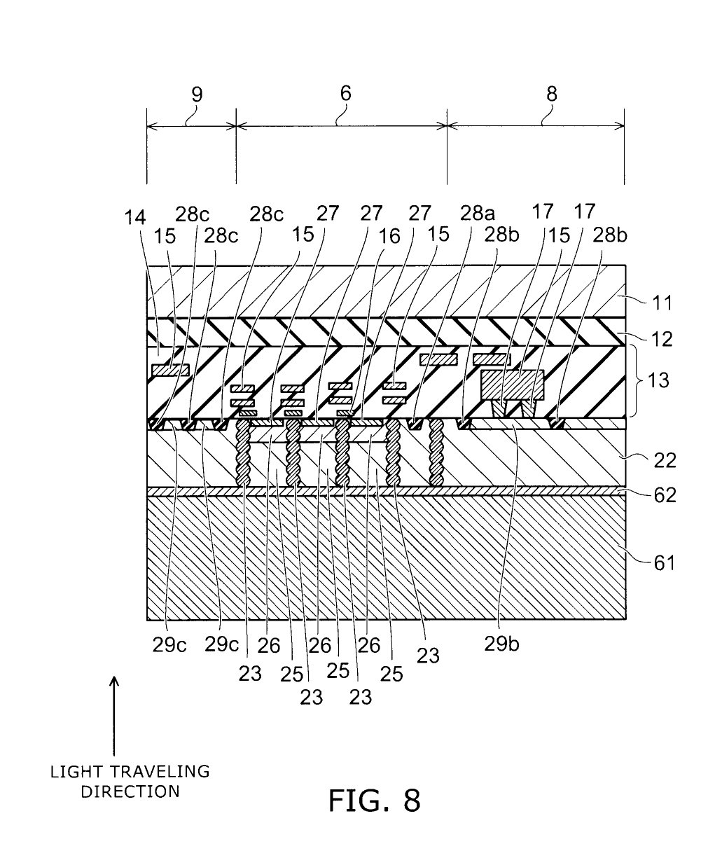

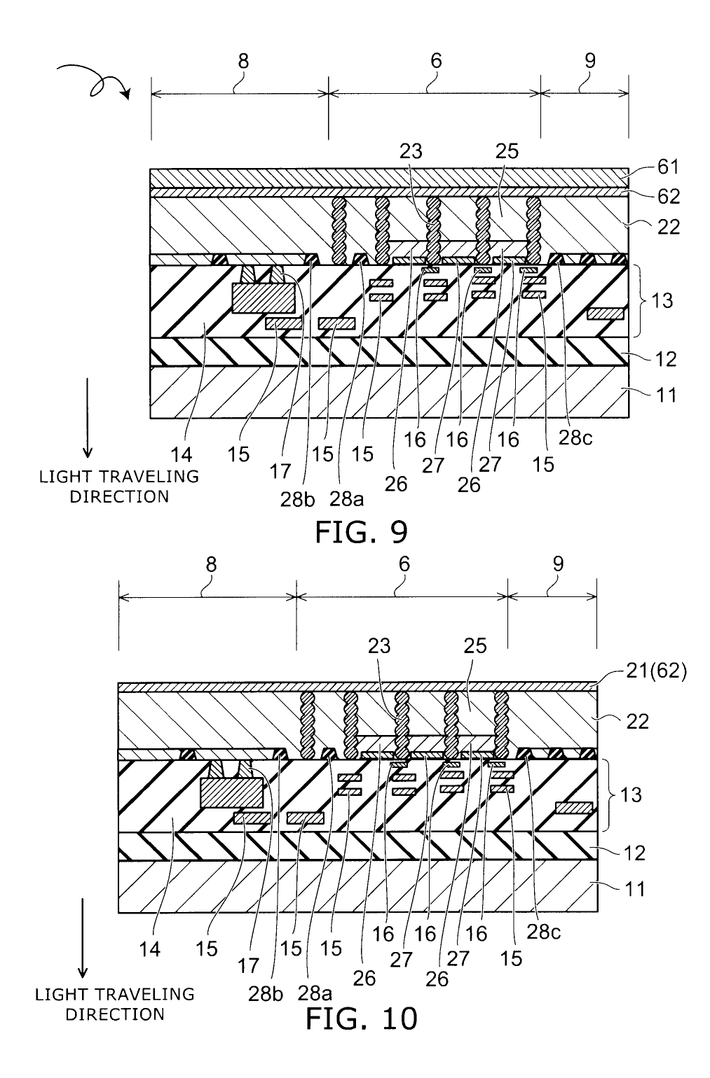

Next, as shown in FIG. 8, a support substrate 11 is laminated to the upper surface of the passivation film 12 by, for example, a direct lamination process using plasma treatment. In other words, the support substrate 11 is attached to the upper surface of the multilayer wiring layer 13 via the passivation film 12. The support substrate 11 is illustratively a silicon wafer. In the subsequent processes, the surface on the support substrate 11 side serves as a fixed surface. Thus, FIG. 9 to FIG. 26 are vertically inverted again and directed in the same direction as FIG. 2. Furthermore, references to “above” and “below” in the following description are also conformed to FIG. 9 to FIG. 26.

Next, as shown in FIG. 9, the substrate 60 is mechanically grounded by, for example, a grinder from the p⁺-type base material 61 side to reduce the thickness of the p⁺-type base material 61. Thereby, the thickness of the p⁺-type base material 61 is made approximately 10 μm.

Next, as shown in FIG. 10, the p⁺-type base material 61 (see FIG. 9) is removed by wet processing. This wet processing is performed by using, for example, a mixed solution of hydrofluoric acid, nitric acid, and acetic acid. By adjusting the mixing ratio and temperature of the mixed solution of hydrofluoric acid, nitric acid, and acetic acid, its concentration selectivity with respect to silicon can be controlled. Here, the concentration selectivity with respect to silicon refers to the property in which the etching rate varies with the impurity concentration in silicon.

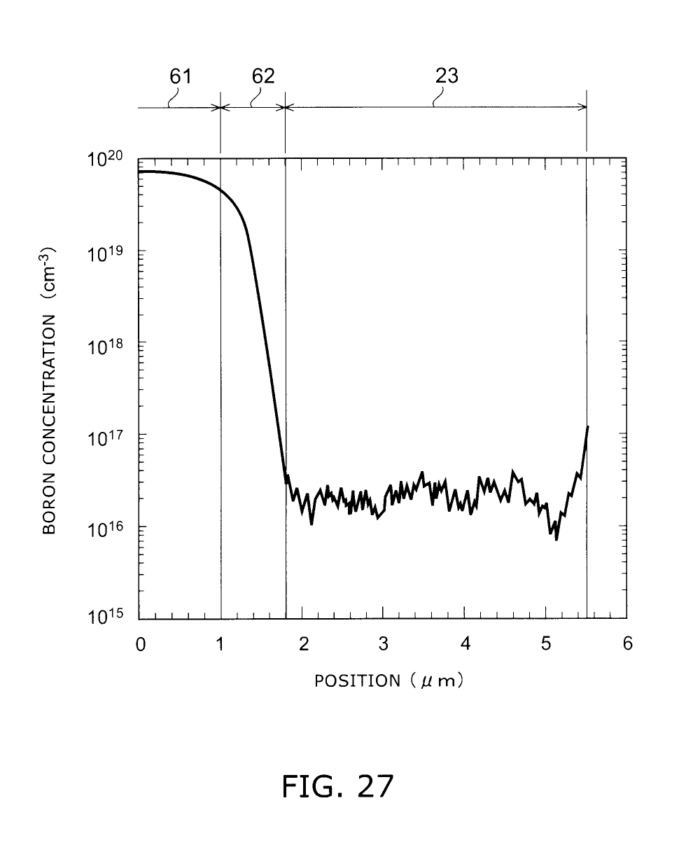

FIG. 27 is a graph illustrating the boron concentration profile in the p⁺-type base material 61, the p-type diffusion layer 62, and the n-type layer 22, where the horizontal axis represents a position in a vertical direction, and the vertical axis represents boron concentration.

In the example shown in FIG. 27, the boron concentration of the p⁺-type base material 61 is approximately 8×10¹⁹ cm⁻³. The thickness of the p-type diffusion layer 62 formed by penetration of boron is 0.8 μm, and its boron concentration continuously decreases from the interface with the p⁺-type base material 61 toward the interface with the p-type barrier region 23. In addition, the boron concentration of the p-type barrier region 23 is approximately 2×10¹⁶ cm⁻³. Accordingly, the connecting portion between the p-type diffusion layer 62 and the p-type barrier region 23 is approximately 2×10¹⁶ cm⁻³. In this case, the aforementioned mixed solution needs to have concentration selectivity such that the p-type barrier region 23 is not etched. For example, the concentration selectivity is such that the etching rate significantly varies at an impurity concentration of 1×10¹⁹ cm⁻³. Thereby, only a silicon portion with the impurity concentration higher than 1×10¹⁹ cm⁻³ is etched, and a silicon portion with the impurity concentration less than 1×10¹⁹ cm⁻³ is barely etched.

By performing wet processing under such condition, etching can be stopped halfway through the p-type diffusion layer 62. Thereby, the p⁺-type base material 61 is completely removed, the p-type diffusion layer 62 is partly removed, and the residual portion of the p-type diffusion layer 62 constitutes a p-type layer 21. The thickness of the p-type layer 21 is, for example, 0.4 μm. The n-type layer 22 and the p-type layer 21 constitute a silicon substrate 20.

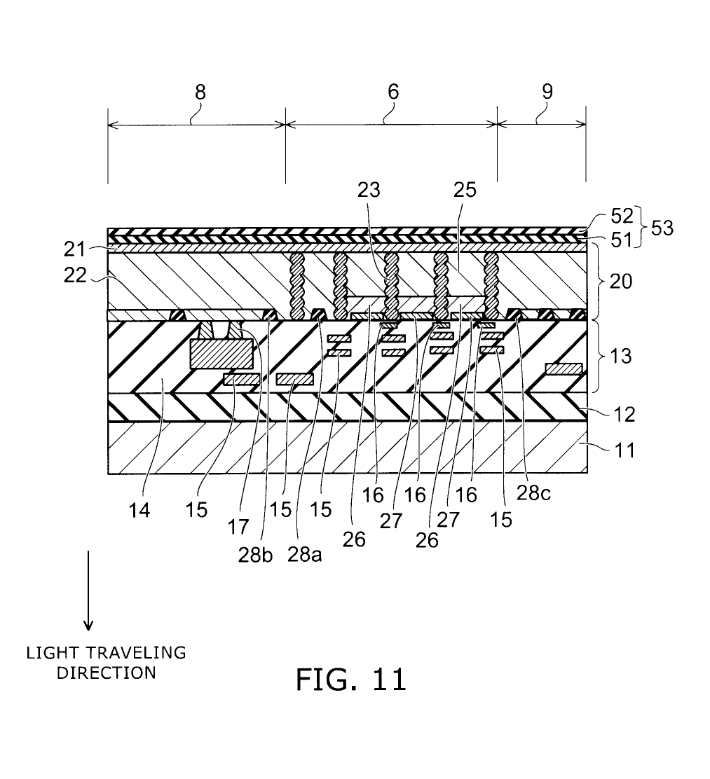

Next, as shown in FIG. 11, a silicon oxide film 51 is formed on the silicon substrate 20, and a silicon nitride film 52 is formed thereon. The silicon oxide film 51 and the silicon nitride film 52 constitute an anti-reflection film 53. At this time, from the viewpoint of optical characteristics, for example, the film thickness of the silicon oxide film 51 is set to 20 nm, and the film thickness of the silicon nitride film 52 is set to 50 nm. At this time, the silicon oxide film 51 is preferably formed by ALD (atomic layer deposition). This is because interface levels between the silicon oxide film 51 and the p-type layer 21 can be reduced by atomic layer replacement if the silicon oxide film 51 is formed by ALD. In contrast, if the silicon oxide film 51 is formed by PVD (physical vapor deposition), the bonding energy between the silicon oxide film 51 and dangling bonds in the superficial layer of the p-type layer 21 decreases. Hence, it is difficult to sufficiently reduce interface levels. Here, the silicon nitride film 52 may be formed by PVD.

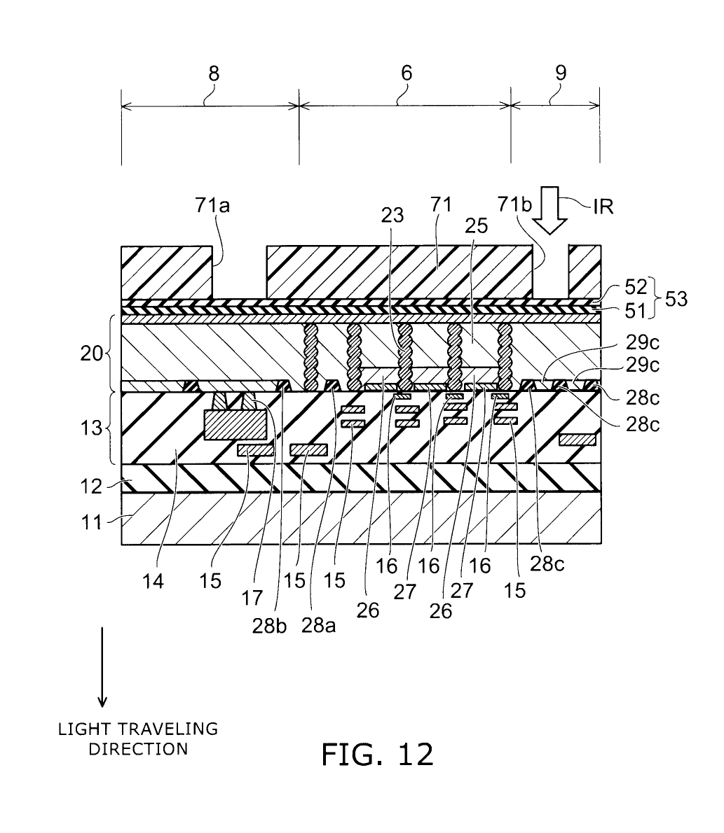

Next, as shown in FIG. 12, a resist film 71 is applied onto the anti-reflection film 53. By exposure and development, openings 71a and 71b are formed in the resist film 71 in the electrode pad region 8 and the mark material region 9, respectively. At this time, by irradiation with infrared radiation IR from above, the silicide layer 29c of the mark material region 9 is optically detected and used as an alignment mark. In an example, the opening width of the opening 71a is set to 10 μm, and the opening width of the opening 71b is set to 50 μm. In this case, the alignment accuracy only needs to be approximately ±1 μm, and highly accurate alignment is not required.

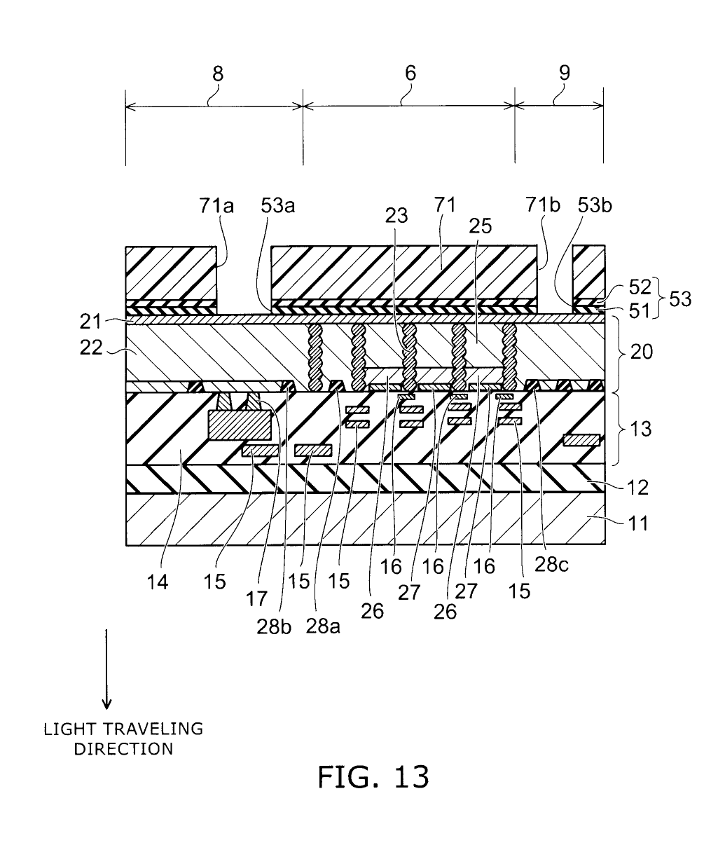

Next, as shown in FIG. 13, dry etching is performed by using the resist film 71 as a mask and using the silicon substrate 20 as a stopper to remove the anti-reflection film 53 from a region immediately below the openings 71a and 71b. Thereby, an opening 53a is formed in a portion of the anti-reflection film 53 located in the electrode pad region 8, and an opening 53b is formed in a portion of the anti-reflection film 53 located in the mark material region 9. In other words, the anti-reflection film 53 is not formed in a region immediately above the silicide layer 29c. Subsequently, the resist film 71 is removed by, for example, ashing treatment with oxygen plasma.

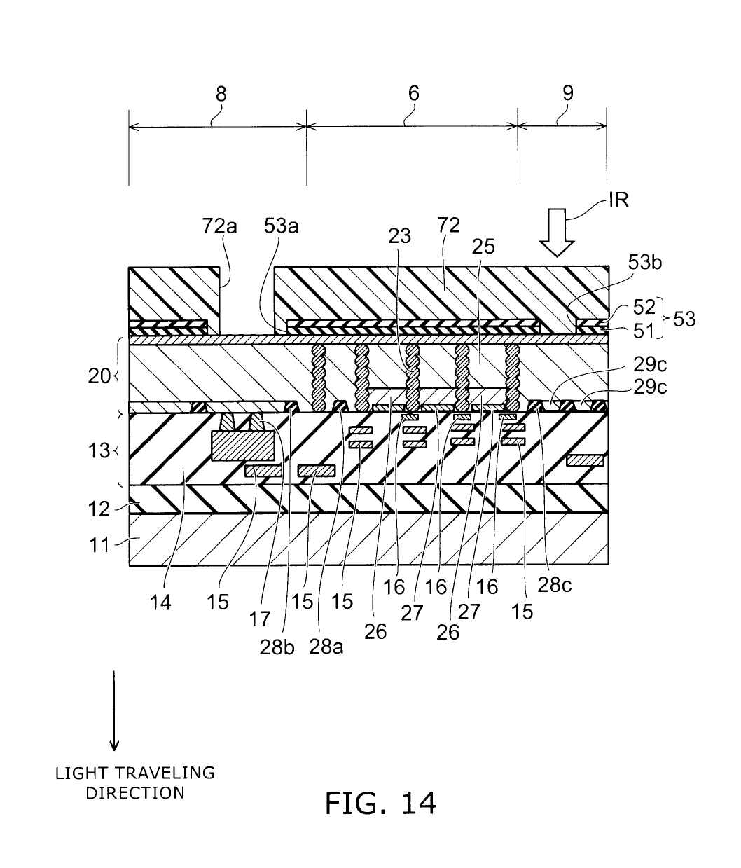

Next, as shown in FIG. 14, a resist film 72 is applied onto the anti-reflection film 53. By exposure and development, an opening 72a is formed in part of a portion of the resist film 72 located in the electrode pad region 8. The opening 72a is formed inside the opening 53a. At this time, by irradiation with infrared radiation IR from above, the silicide layer 29c of the mark material region 9 is used as an alignment mark. In an example, when the opening width of the opening 53a is 10 μm, the opening width of the opening 72a is set to 7 μm. In this case, the alignment accuracy only needs to be approximately ±1 μm, and highly accurate alignment is not required.

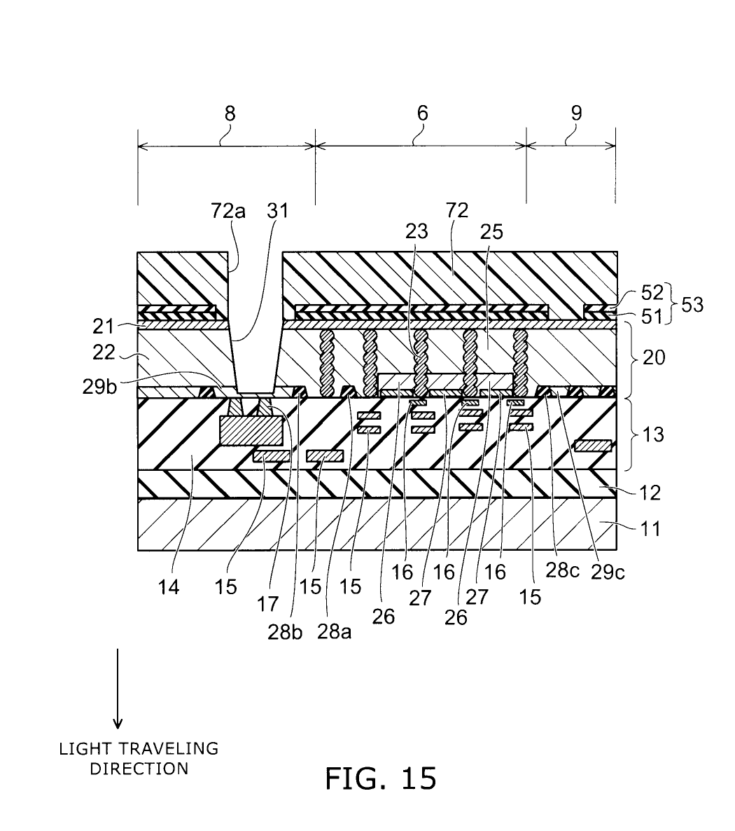

Next, as shown in FIG. 15, dry etching is performed by using the resist film 72 as a mask and using the silicide layer 29b as a stopper to remove the p-type layer 21 and the n-type layer 22 from a region immediately below the opening 72a. Thereby, a through hole 31 is formed in the silicon substrate 20. Preferably, the through hole 31 has a forward taper shape narrowing downward, and the taper angle is 75 to 89°. Subsequently, the resist film 72 is removed by, for example, ashing treatment with oxygen plasma.

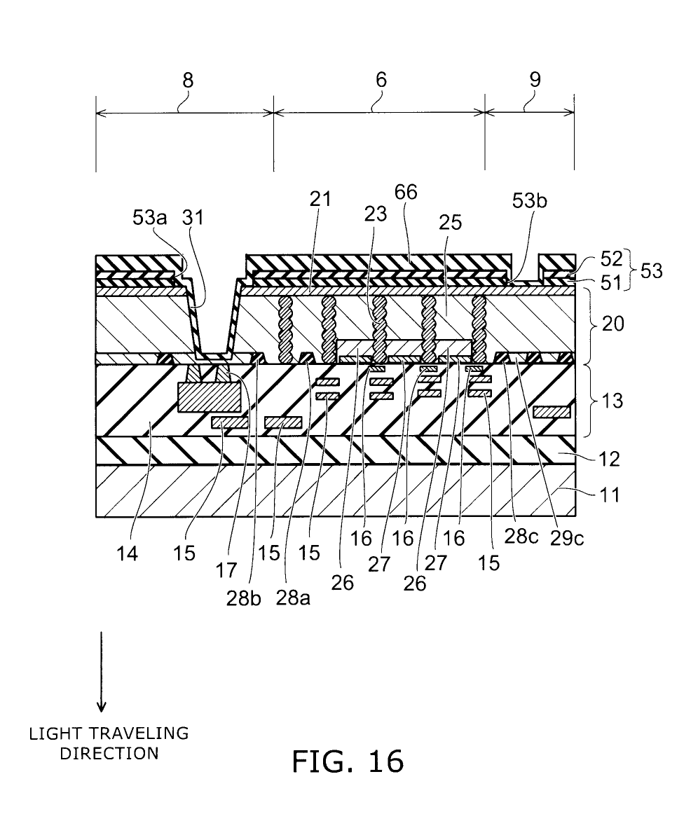

Next, as shown in FIG. 16, a silicon oxide film 66 is formed on the entire surface by a low temperature process such as CVD (chemical vapor deposition). At this time, the silicon oxide film 66 is formed not only on the upper surface of the anti-reflection film 53 but also on the side surface and bottom surface of the through hole 31, on the side surface of the opening 53a of the anti-reflection film 53, and on the side surface and bottom surface of the opening 53b.

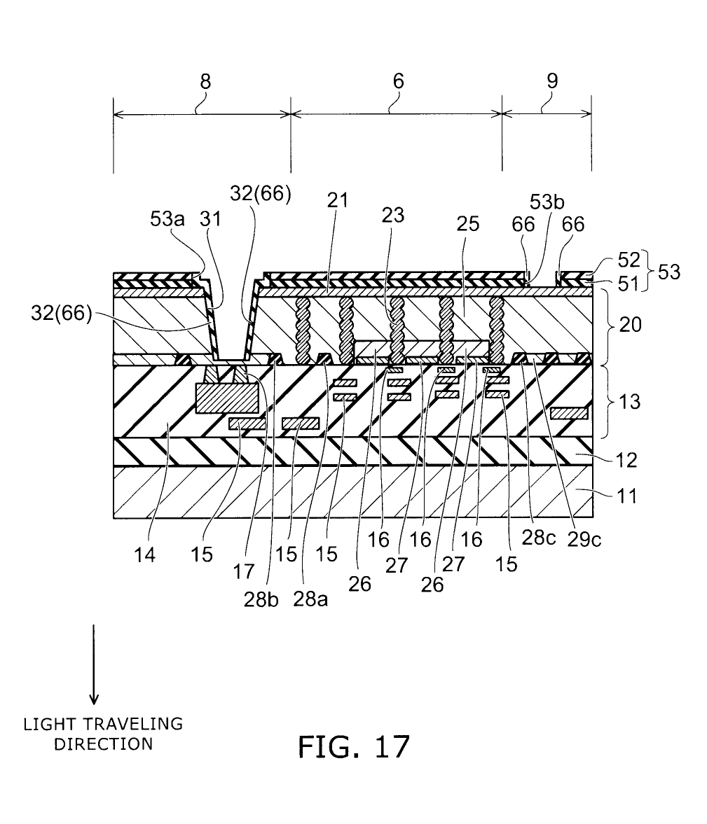

Next, as shown in FIG. 17, dry etching using the silicon nitride film 52 as a stopper is performed on the entire surface to etch back the silicon oxide film 66. Thereby, a portion of the silicon oxide film 66 located on the upper surface of the anti-reflection film 53, a portion of the silicon oxide film 66 located on the bottom surface of the through hole 31, and a portion of the silicon oxide film 66 located on the bottom surface of the opening 53b of the anti-reflection film 53 are removed, and a portion of the silicon oxide film 66 located on the side surface of the through hole 31, a portion of the silicon oxide film 66 located on the side surface of the opening 53a, and a portion of the silicon oxide film 66 located on the side surface of the opening 53b are left. Thereby, the portions of the silicon oxide film 66 located on the side surface of the through hole 31 and on the side surface of the opening 53a constitute a side surface protective film 32.

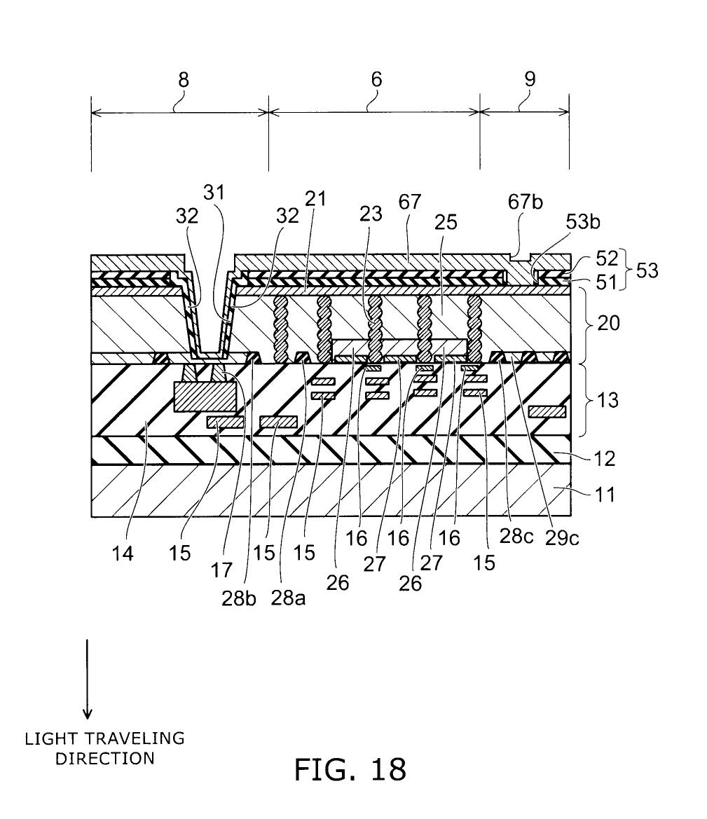

Next, as shown in FIG. 18, a two-layer film (not shown) formed of a titanium layer and a titanium nitride layer is formed as a barrier metal. Then, aluminum is deposited by sputtering to form an aluminum layer 67. The thickness of the aluminum layer 67 is, for example, 330 nm. At this time, because the through hole 31 is formed in a forward taper shape in the process shown in FIG. 15, the aluminum layer 67 is continuously formed also on the side surface of the through hole 31. Furthermore, a level difference 67b reflecting the opening 53b is formed in the upper surface of the aluminum layer 67.

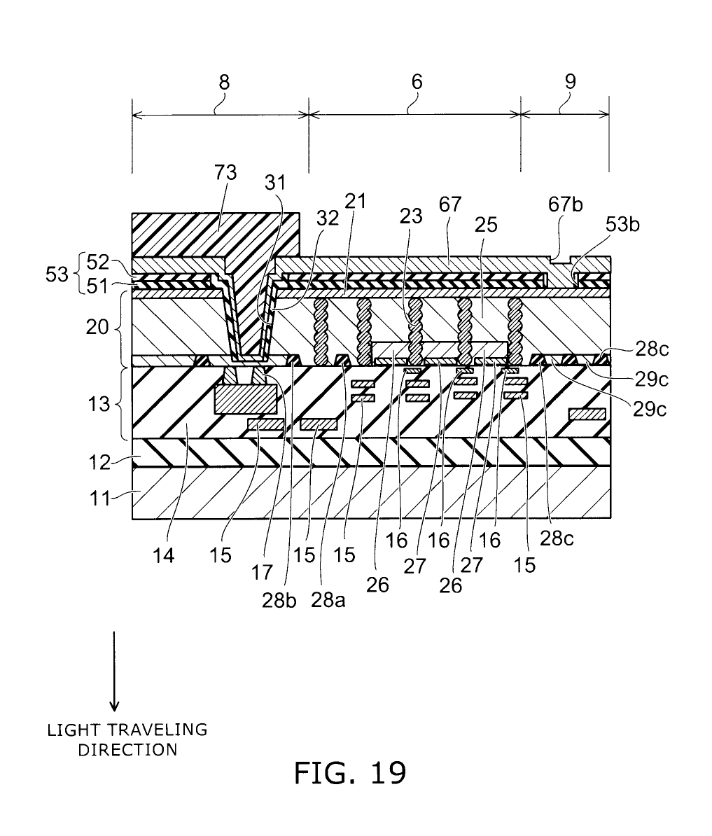

Next, as shown in FIG. 19, a resist film 73 is applied to the entire surface. By exposure and development, the resist film 73 is patterned so as to cover the electrode pad region 8. At this time, because the mark material region 9 is covered with the aluminum layer 67, it is impossible to detect the silicide layer 29c by irradiation with infrared radiation and to use the silicide layer 29c as an alignment mark. Thus, the level difference 67b reflecting the opening 53b in the upper surface of the aluminum layer 67 is used as alignment mark. The alignment accuracy in this patterning only needs to be approximately ±1 μm, and highly accurate alignment is not required.

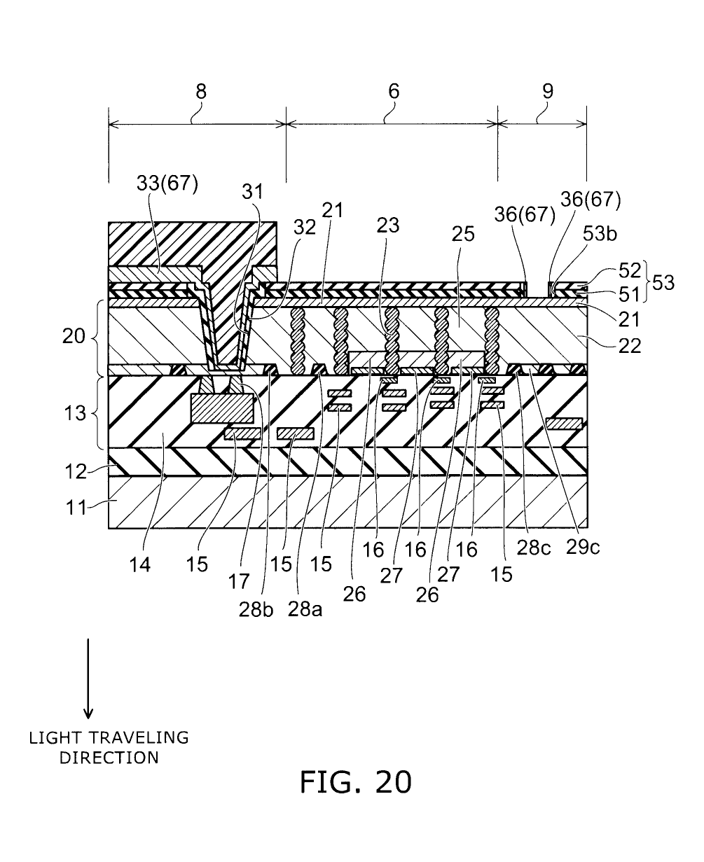

Next, as shown in FIG. 20, dry etching is performed by using the resist film 73 as a mask and using the silicon nitride film 52 as a stopper to remove the aluminum layer 67 from a region except the electrode pad region 8. At this time, the aluminum layer 67 is left in the electrode pad region 8 to constitute an electrode film 33. The electrode film 33 is formed not only on the upper surface of the anti-reflection film 53 but also on the inner surface of the through hole 31. Furthermore, the aluminum layer 67 is left also on the side surface of the opening 53b of the anti-reflection film 53 to constitute a frame-shaped fence 36. In contrast, the aluminum layer 67 is removed from the light receiving region 6. Furthermore, the aluminum layer 67 is removed also from above the bottom surface of the opening 53b. Subsequently, the resist film 73 is removed by, for example, ashing treatment with oxygen plasma.

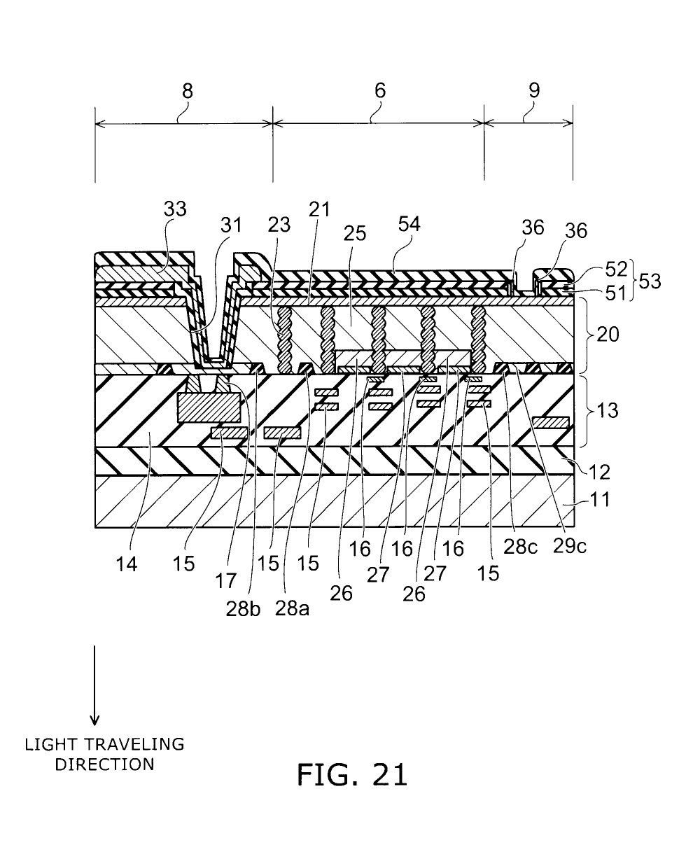

Next, as shown in FIG. 21, silicon oxide is deposited on the entire surface by, for example, PVD to form a cap film 54. At this point, the cap film 54 covers entirely the electrode film 33. Although the cap film 54 is illustratively a silicon oxide film in this embodiment, the cap film 54 may be a two-layer film formed of a silicon oxide film and a silicon nitride film.

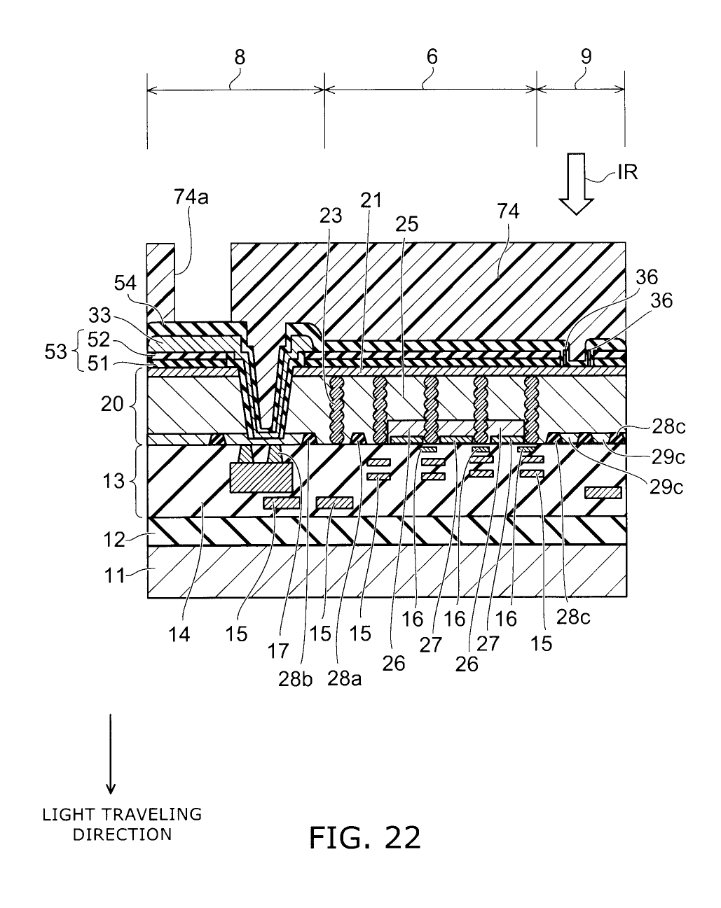

Next, as shown in FIG. 22, a resist film 74 is applied to the entire surface. By exposure and development, an opening 74a is formed in part of the electrode pad region 8. The opening 74a is formed in a region intended to form an electrode pad 35 (see FIG. 2). At this time, by irradiation with infrared radiation IR from above, the silicide layer 29c is detected and used as an alignment mark. Alternatively, the fence 36 may be detected and used as an alignment mark. The opening 74a has, for example, a square shape with rounded corners with a length of, for example, 50 μm on a side. In this case, the alignment accuracy only needs to be e.g. ±1 μm, and highly accurate alignment is not required.

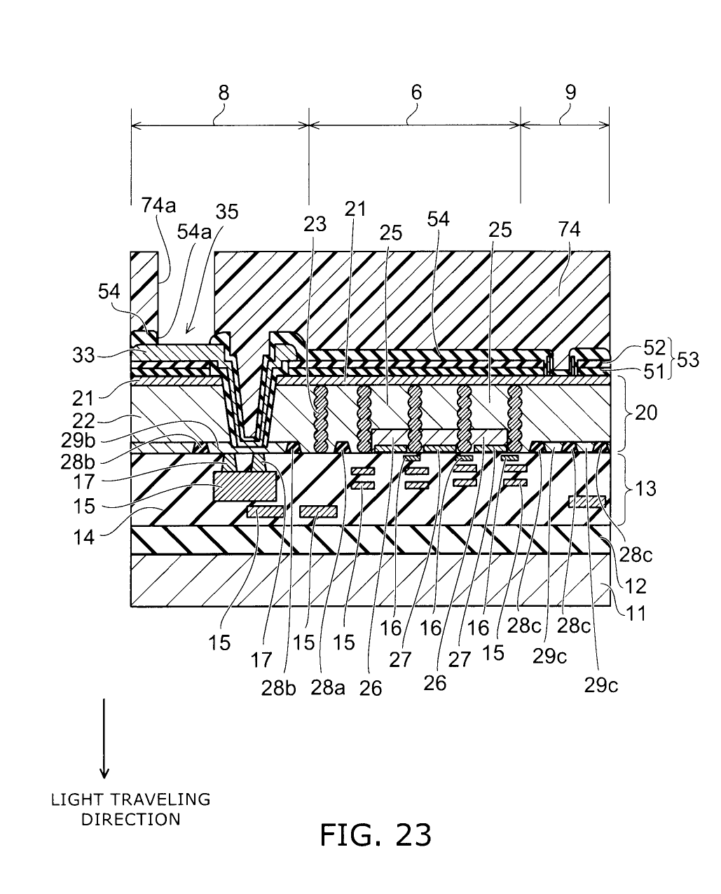

Next, as shown in FIG. 23, dry etching is performed by using the resist film 74 as a mask and using the electrode film 33 as a stopper. Thereby, the cap film 54 is selectively removed in a region immediately below the opening 74a to form an opening 54a. In the opening 54a, the electrode film 33 is exposed to constitute an electrode pad 35. Subsequently, the resist film 74 is removed by, for example, ashing treatment with oxygen plasma.

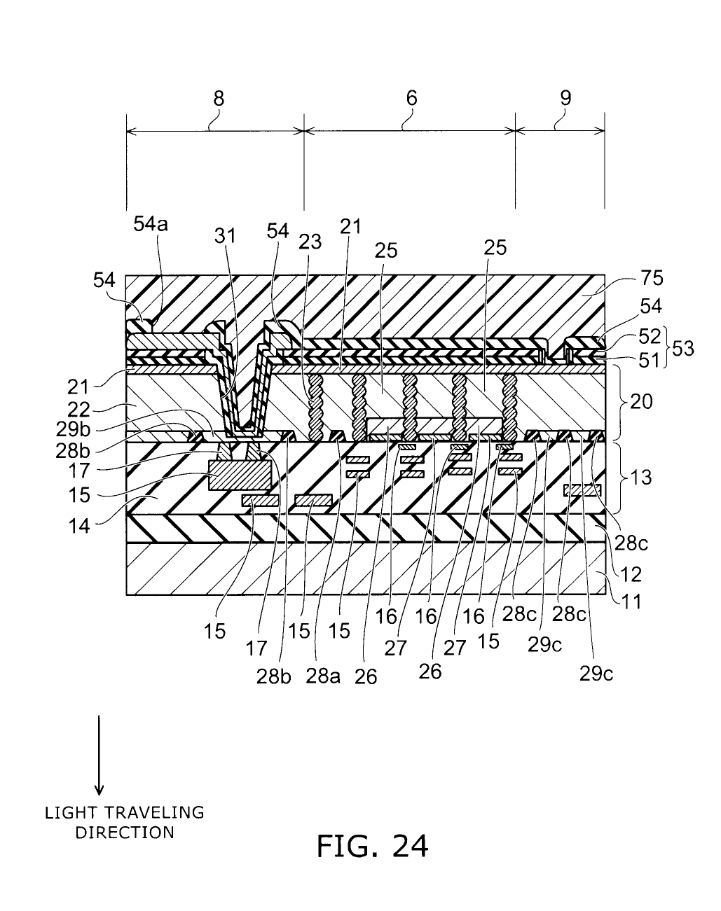

Next, as shown in FIG. 24, a thick resist film 75 is formed on the entire surface. The resist film 75 has a film thickness such as to completely fill up the through hole 31.

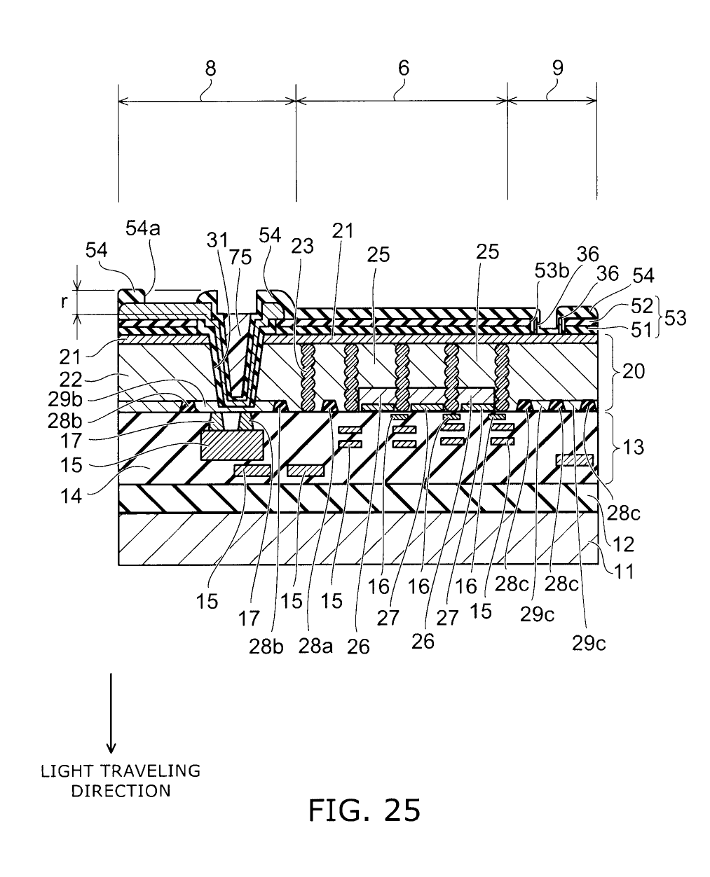

Next, as shown in FIG. 25, the resist film 75 is etched back by dry etching or CDE (chemical dry etching). At this time, the resist film 75 is left in the through hole 31. This resist film 75 serves as a dummy material. The recess amount r of the resist film 75 left in the through hole 31, i.e., the depth of the upper surface of the resist film 75 with reference to the upper surface of the cap film 54, is preferably 2 μm or less, and more preferably 1.5 μm or less.

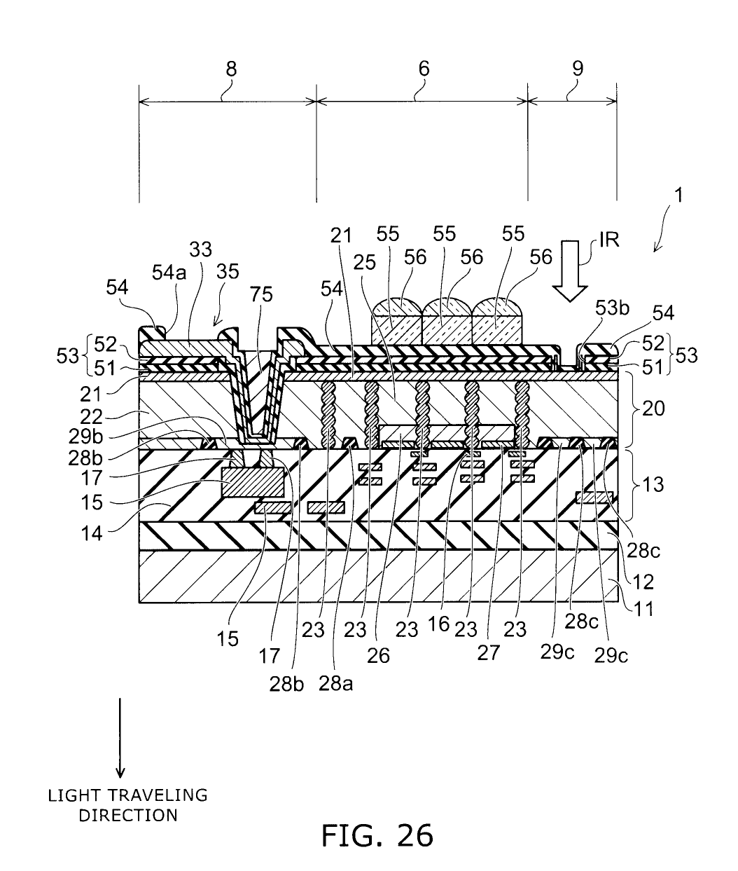

Next, as shown in FIG. 26, in the light receiving region 6, red, green, and blue color filters 55 are formed on the cap film 54. Specifically, the processes of applying a liquid color filter material onto the cap film 54, solidifying this color filter material, and patterning the solidified color filter material are repeated by the number of colors. At this time, the boundary between the color filters 55 is positioned in a region immediately above the p-type barrier region 23. For alignment of this positioning, the silicide layer 29c is used as an alignment mark. More specifically, irradiation with infrared radiation IR from above is performed. This infrared radiation IR is injected into the silicon substrate 20 via the opening 53b of the anti-reflection film 53 in the mark material region 9, transmitted through the silicon substrate 20, reflected by the silicide layer 29c, transmitted again through the silicon substrate 20, and emitted out via the opening 53b. By receiving this emitted infrared radiation, the silicide layer 29c is optically detected and used as a reference for alignment of the positioning.

Next, a microlens 56 is formed on the color filter 55. Next, the resist film 75 buried in the through hole 31 is removed by, for example, a thinner solution and the like. Here, this resist film 75 may not be removed. Thus, the solid-state imaging device 1 according to this embodiment is manufactured.

Next, the function and effect of this embodiment will now be described.

In the solid-state imaging device 1 according to this embodiment, in the mark material region 9, a silicide layer 29c is formed in the lower surface of the silicon substrate 20, i.e., the surface on the multilayer wiring layer 13 side. The silicide layer 29c has higher light reflectance than silicon oxide forming the device isolation film 28c and the interlayer insulating film 14 and silicon forming the silicon substrate 20. Hence, when the silicon substrate 20 is irradiated with infrared radiation from above, this infrared radiation reaches the silicide layer 29c and is reflected upward. This reflected light creates contrast between the silicide layer 29c and its surroundings. As a result, by receiving this reflected light, the silicide layer 29c can be optically detected. Thereby, the silicide layer 29c can be used as an alignment mark in each process. In particular, in the process of forming color filters 55 shown in FIG. 26, the silicide layer 29c can be used for accurate alignment so that the boundary of the color filter 55 is positioned in the region immediately above the p-type barrier region 23.

In other words, according to this embodiment, the color filter 55 can be positioned with reference to the silicide layer 29c. On the other hand, as described above, the p-type barrier region 23 is positioned with reference to the device isolation film 28a. The silicide layer 29c is formed in a self-aligned manner with respect to the device isolation film 28c, and the device isolation film 28c is formed simultaneously with the device isolation film 28a. Hence, no misalignment occurs between the silicide layer 29c and the device isolation film 28a. Accordingly, the p-type barrier region 23 and the color filter 55 can be positioned in first-order alignment based on a common reference given by the device isolation films 28a and 28c. Hence, alignment between the p-type barrier region 23 and the color filter 55 can be performed with very high accuracy. Thereby, high integration of pixels can be achieved.

Contrarily, in the case where the alignment accuracy between the p-type barrier region 23 and the color filter 55 only needs to satisfy a prescribed standard, a large alignment margin can be provided to the color filter 55.

In the following, this effect will be described with reference to example dimensions of each portion.

In the case where the width of the PD region 25 is 1.15 μm and the width of the p-type barrier region 23 is 0.25 μm with a variation of 10%, the minimum of the width of the p-type barrier region 23 is 0.225 μm. Accordingly, the allowable variation width for the position of the boundary of the color filter 55 is ±0.1125 μm (=0.225 μm/2) or less. As described above, the p-type barrier region 23 is aligned with reference to the device isolation film 28a. The alignment accuracy in this alignment is ±0.05 μm. In the case where the alignment accuracy of the color filter 55 with reference to the device isolation film 28c is ±x μm, the cumulated alignment error can be calculated by mean square sum. Accordingly, it is only necessary to satisfy √(0.05²+x²)≦0.1125. This yields x≦√(0.1125²−0.05²)≦0.10 μm. Thus, the alignment accuracy of the color filter 55 can be relaxed to ±0.10 μm.

In contrast, for example, in the case where the color filter 55 is positioned with reference to the transfer gate 16, the color filter 55 is indirectly positioned in the order of the device isolation film 28a, transfer gate 16, and color filter 55 because the transfer gate 16 is positioned with reference to the device isolation film 28a. In the case where the alignment accuracy in positioning the transfer gate 16 with reference to the device isolation film 28a is ±0.025 μm and the alignment accuracy in positioning the color filter 55 with reference to the transfer gate 16 is ±y μm, it is necessary to satisfy √(0.05²+0.025²)+y≦0.1125 because the alignment accuracy of the p-type barrier region 23 with reference to the device isolation film 28a is ±0.05 μm. This yields y≦0.0566 μm. Hence, the alignment accuracy of the color filter 55 needs to be ±0.056 μm, requiring alignment with very high accuracy.

Furthermore, in this embodiment, in the mark material region 9, an opening 53b is formed in the anti-reflection film 53. The opening 53b can be used as an opening window for detecting an alignment mark. Thus, infrared radiation is not blocked by the anti-reflection film 53, and the detection accuracy of the silicide layer 29c can be improved. Furthermore, by forming the opening 53b, a level difference 67b can be formed in the upper surface of the aluminum layer 67 in the process shown in FIG. 18. Thereby, in patterning the resist film 73 in the process shown in FIG. 19, the level difference 67b can be used as an alignment mark. In the process shown in FIG. 19, this effect is particularly advantageous because the silicide layer 29c cannot be detected by the presence of the aluminum layer 67 provided on the entire surface.

In addition, in this embodiment, infrared radiation is used as light for detecting the silicide layer 29c. The transmittance of infrared radiation in silicon is higher than that of ultraviolet radiation or visible light. Hence, use of infrared radiation facilitates detecting the silicide layer 29c.

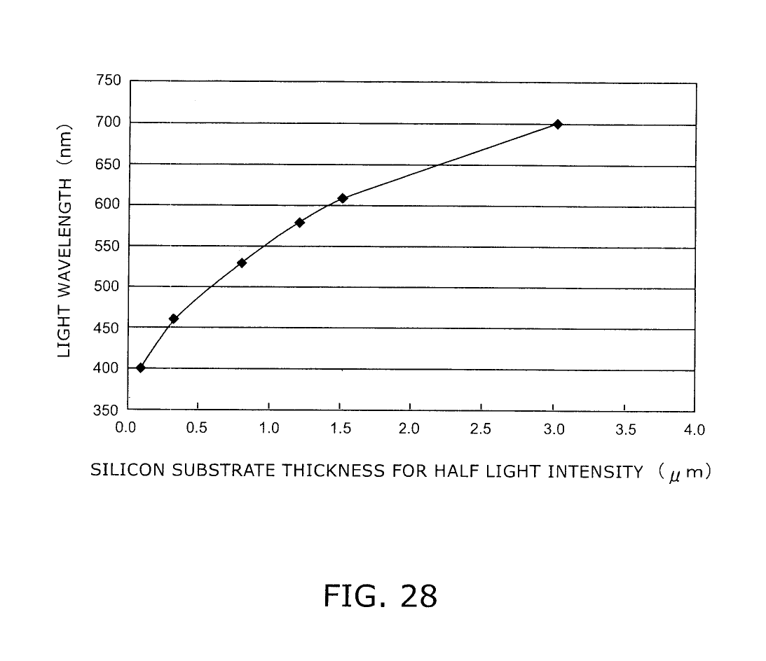

FIG. 28 is a graph illustrating the attenuation behavior of light in silicon, where the horizontal axis represents the thickness of the silicon substrate reducing the intensity of incident light by half, and the vertical axis represents the wavelength of incident light.

As shown in FIG. 28, for a longer wavelength of light incident on the silicon substrate, the thickness of the silicon substrate reducing the intensity by half is thicker. In other words, the light transmittance increases. For example, the thickness of the silicon substrate reducing by half the intensity of infrared radiation with a wavelength of 700 nm is approximately 3 μm. Accordingly, if the thickness of the silicon substrate 20 is 3 μm and the reflectance at the silicide layer 29c is 100%, approximately a quarter of infrared radiation incident on the silicon substrate 20 is emitted from the silicon substrate 20 and can be received. As a result, the silicide layer 29c can be detected sufficiently with accuracy. Even if the thickness of the silicon substrate 20 is 5 μm, the silicide layer 29c can be detected if infrared radiation is used.

The thickness of the silicon substrate 20 is approximately 3 to 5 μm. The reason for this is as follows. If the thickness of the silicon substrate 20 is less than 3 μm, the volume of the PD region 25 is insufficient, and the light receiving efficiency for red light decreases. On the other hand, if the thickness of the silicon substrate 20 is larger than 5 μm, it is difficult to form the p-type barrier region 23 by ion implantation.

In addition, in the solid-state imaging device 1 according to this embodiment, in the electrode pad region 8, a through hole 31 is formed in the silicon substrate 20. Furthermore, an electrode film 33 is continuously formed on the bottom surface and side surface of the through hole 31 and on the upper surface of the silicon substrate 20 in the electrode pad region 8. Thereby, the electrode film 33 is connected to the metal wiring 15 of the multilayer wiring layer 13 via the silicide layer 29b at the bottom surface of the through hole 31 and extracted to above the upper surface of the silicon substrate 20. This extracted portion constitutes an electrode pad 35 to which an external wiring W is to be bonded. As a result, the external wiring W is connected to the metal wiring 15 via the electrode film 33 made of metal. Thereby, the parasitic resistance between the external wiring W and the metal wiring 15 can be reduced, and the parasitic capacitance can be reduced.

In addition, the through hole 31 is not formed in a region immediately below a portion of the electrode film 33 constituting the electrode pad 35, but the silicon substrate 20 is provided throughout the immediately underlying region of the electrode pad 35. Thus, the immediately underlying region of the electrode pad 35 has high strength. Hence, even when an external wiring W is bonded to the electrode pad 35, there is no damage to the silicon substrate 20. That is, high mounting strength is achieved. Furthermore, because the electrode pad 35 is located on the upper surface of the silicon substrate 20, the electrode pad 35 has a flat surface. This facilitates bonding of an external wiring W.

In addition, in this embodiment, the through hole 31 has a forward taper shape narrowing downward. This facilitates continuously forming the electrode film 33 on the side surface of the through hole 31. Thereby, the electrode film 33 is less prone to step discontinuity.

In addition, a side surface protective film 32 is provided on the inner surface of the through hole 31. The electrode film 33 is provided on the side surface protective film 32. Hence, the silicon substrate 20 is insulated from the electrode film 33 by the side surface protective film 32. Thus, the potential of the silicon substrate 20 is not varied by the potential of the electrode film 33.

In addition, the side surface of the through hole 31 is entirely covered with the side surface protective film 32, the electrode film 33, and the cap film 54. Hence, the silicon substrate 20 is not exposed at the side surface of the through hole 31. Thus, there is no case where moisture and the like adsorb on the exposed surface of the silicon substrate 20 and decrease the reliability of the solid-state imaging device 1.

In addition, in this embodiment, when the color filter 55 is formed in the process shown in FIG. 26, the resist film 75 is buried as a dummy material in the through hole 31. Thus, when a liquid color filter material is applied, the color filter material can be prevented from flowing into the through hole 31. This can prevent the color filter 55 from being thinned near the through hole 31. To achieve this effect, the recess amount r of the resist film 75 buried in the through hole 31 is preferably 2 μm or less, and more preferably 1.5 μm or less.

Hereinabove, the invention is described with reference to exemplary embodiments. However, the invention is not limited to the embodiments. Those skilled in the art can suitably modify the above embodiment by addition, deletion, or design change of components, or by addition, omission, or condition change of processes, and such modifications are also encompassed within the scope of the invention as long as they fall within the spirit of the invention.

For example, although an example is illustrated in the above embodiment in which a silicide layer is used as an alignment mark, the invention is not limited thereto. It is sufficient that the alignment mark is a metallic layer which can be formed in the surface of the semiconductor substrate. The metallic layer refers to a layer containing free electrons. Because of free electrons contained therein, the metallic layer exhibits metallic luster and can efficiently reflect light. Thereby, the metallic layer has higher light reflectance than the semiconductor substrate and the multilayer wiring layer and can be optically detected more easily. The metallic layer includes, for example, a layer made of a pure metal, a layer made of an alloy, and a layer made of a metal compound, and also includes a silicide layer. If the semiconductor substrate is formed from silicon and the metallic layer is made of a silicide layer, the metallic layer can be easily formed. Furthermore, the metallic layer can be formed in a self-aligned manner with respect to the device isolation film made of silicon oxide or the like.

Furthermore, although an example is illustrated in the above embodiment in which infrared radiation is used as light for detecting the silicide layer 29c, the invention is not limited thereto. Visible light may be used, for example. In this case, the opening 53b may not be formed in the anti-reflection film 53.

The embodiment described above can provide a solid-state imaging device and a method for manufacturing the same, which can achieve high integration of pixels.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A solid-state imaging device comprising:
a multilayer wiring layer;
a semiconductor substrate provided on the multilayer wiring layer and including a first conductivity type layer;
an impurity diffusion region of a second conductivity type partitioning the first conductivity type layer into a plurality of regions;
an anti-reflection film provided on the semiconductor substrate;
a color filter provided on the anti-reflection film for each of the partitioned regions; and
a metallic layer formed in a region of a lower surface of the semiconductor substrate except the partitioned regions,
the anti-reflection film not being provided in a region immediately above the metallic layer.

2. The device according to claim 1, wherein the semiconductor substrate is formed from silicon, and the metallic layer is formed from silicide.

3. The device according to claim 1, further comprising:
a device isolation film formed in a region of the lower surface of the semiconductor substrate except the partitioned regions,
the metallic layer being located in a region partitioned by the device isolation film.

4. The device according to claim 1, further comprising:
an electrode film provided on a partial region of an upper surface of the semiconductor substrate and on an inner surface of a through hole formed in the first conductivity type layer, the electrode film being connected to a wiring of the multilayer wiring layer.

5. The device according to claim 4, wherein the through hole is formed in a plurality so as to surround the partial region.

6. The device according to claim 4, further comprising:
one other metallic layer provided in a region including an immediately underlying region of the through hole between the multilayer wiring layer and the semiconductor substrate,
the electrode film being connected to the wiring via the one other metallic layer.

7. The device according to claim 4, further comprising:
a cap film provided between the semiconductor substrate and the color filter, the cap film covering a part of a portion of the electrode film located on the upper surface of the semiconductor substrate, a portion of the electrode film located on the inner surface of the through hole, and a region of the upper surface of the semiconductor substrate immediately above the metallic layer, the cap film not covering a remaining part of the portion of the electrode film located on the upper surface of the semiconductor substrate.

8. The device according to claim 7, wherein the remaining part is an electrode pad, an external wiring being bonded to the electrode pad.

9. The device according to claim 1, wherein the impurity diffusion region is shaped like a lattice.

10. The device according to claim 1, further comprising:
a support substrate located below the multilayer wiring layer.

11. A solid-state imaging device comprising:
a multilayer wiring layer;
a semiconductor substrate provided on the multilayer wiring layer and including a first conductivity type layer;
an impurity diffusion region of a second conductivity type partitioning the first conductivity type layer into a plurality of regions; and
an electrode film connected to a wiring of the multilayer wiring layer,
a through hole being formed in the first conductivity type layer, and
the electrode film being located on a partial region of an upper surface of the semiconductor substrate and on an inner surface of the through hole.

12. A method for manufacturing a solid-state imaging device, comprising:
forming an impurity diffusion region of a second conductivity type in a substrate to partition a first conductivity type layer into a plurality of regions, at least a lower portion of the substrate being made of a semiconductor material, the first conductivity type layer being provided in the lower portion;
forming a metallic layer in a region of a lower surface of the substrate except the partitioned regions;
forming a multilayer wiring layer below the substrate;
removing an upper portion of the substrate to make the lower portion of the substrate as a semiconductor substrate;
forming an anti-reflection film on at least a part of a region of an upper surface of the semiconductor substrate except a region immediately above the metallic layer; and
forming a color filter on an upper surface of the anti-reflection film for each of the partitioned regions using the metallic layer as an alignment mark.

13. The method according to claim 12, wherein in the forming of the color filter, the metallic layer is optically detected from above the semiconductor substrate.

14. The method according to claim 13, wherein the detection of the metallic layer is performed by irradiating infrared radiation from above the semiconductor substrate and receiving reflected light of the infrared radiation.

15. The method according to claim 12, wherein
the semiconductor material is silicon, and
the forming of the metallic layer includes:
forming an insulating film on the lower surface of the substrate;
selectively removing the insulating film to selectively expose a region of the substrate except the partitioned regions;
depositing a metal layer on the lower surface of the substrate;
reacting silicon in the substrate with metal in the metal layer by heating to form a silicide layer; and
removing the insulating film and an unreacted portion of the metal layer.

16. The method according to claim 12, further comprising:
forming a through hole in the first conductivity type layer after the removing of the upper portion of the substrate; and
forming an electrode film on a part of the upper surface of the semiconductor substrate and on an inner surface of the through hole connected to a wiring of the multilayer wiring layer.

17. The method according to claim 16, wherein
the forming of the color filter is performed after the forming of the through hole, and
the forming of the color filter includes:
burying a dummy material in the through hole;
applying a liquid color filter material on the semiconductor substrate;
solidifying the color filter material; and
patterning the solidified color filter material.

18. The method according to claim 16, wherein in the forming of the metallic layer, the metallic layer is formed also in a region of the lower surface of the substrate immediately below a region intended to form the through hole.

19. The method according to claim 12, wherein as the substrate, a substrate including the first conductivity type layer formed on a lower surface of a second conductivity type layer is used.

20. The method according to claim 12, further comprising,
attaching a support substrate to an upper surface of the multilayer wiring layer after the forming of the multilayer wiring layer and before the removing of the upper portion of the substrate.
